(19) United States
(12) Patent Application Publication
(10) Pub. No.: US 2025/0201693 A1
(43) Pub. Date: Jun. 19, 2025

(54) SIGNAL LINES FOR SEMICONDUCTOR DEVICES

(71) Applicant: Altera Corporation, San Jose, CA (US)

(72) Inventors: Arturo PACHON MUNOZ, San Jose, CA (US); Montserrat BENITO VILLAFRANCA, San Jose, CA (US)

(21) Appl. No.: 18/542,457

(22) Filed: Dec. 15, 2023

(51) Int. Cl. H01L 23/498; H01L 23/00; H01L 25/065

(52) U.S. Cl. CPC H01L 23/49838; H01L 23/49816; H01L 24/08; H01L 24/16; H01L 25/0657; H01L 2224/08146; H01L 2224/08225; H01L 2224/16227; H01L 2224/16235; H01L 2225/06513; H01L 2225/06517; H01L 2924/01029; H01L 2924/1431; H01L 2924/1434; H01L 2924/15311

(57) ABSTRACT

Signal lines that are useful for high speed I/O applications are provided. The signal lines can be used in, for example, semiconductor chip packaging applications. The signal lines include a conductive region and one or more meta-conductive regions having alternating layers of a magnetic material and a non-magnetic material.

### FIELD

Descriptions are generally related to semiconductor devices, and more particular descriptions are related to signal lines and semiconductor device packages.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Electrical signals traveling along a transmission line lose energy. This insertion loss becomes a larger issue at higher signal transmission rates. In addition, losses associated with passive interconnections exhibit frequency dependent behavior that produce inter-symbol interference (ISI). Because of longer ISI tails, more power hungry equalization architectures are used on transmitter and on the received in order to improve signal to noise ratio. Due to constraints of non-linear equalizers, such as, for example, a decision feedback equalizer (DFE), high coefficient tap values may increase the probability of burst errors that can further degrade system performance due to resending packets. If forward error correction (FEC) is not able to fix the error in a codeword, packets are resent.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity in the figures.

FIGS. 1A-1C illustrate exemplary signal lines in a semiconductor package substrate.

FIGS. 2A-2B show two different exemplary signal line configurations.

FIG. 3 illustrates simulation differential insertion loss results for different signal line designs.

FIGS. 4A-4C show exemplary stripline and microstripline designs.

FIG. 5 provides a method for manufacturing an exemplary signal line.

FIG. 6 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or

importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Terms such as chip, die, IC (integrated circuit) chip, IC die, microelectronic chip, microelectronic die, and/or semiconductor chip are interchangeable and refer to a semiconductor device comprising integrated circuits.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a board, system board, logic board, motherboard, or printed circuit board for I/O (input/output) communication and power delivery. A package with multiple dies can, for example, be a system in a package.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry). Other components can be semiconductor processing and/or testing equipment that is able to perform physical operations such as, for example, lithography, probing, material deposition (for example, chemical vapor deposition, atomic layer deposition, and/or sputtering), chemical mechanical polishing, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with airgaps. Dielectric layers that include conducting features can be intermetal dielectric (ILD) features.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, aluminum-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, aluminum-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, exemplary solid amorphous glass substrate cores can be considered to have a rectangular prism volume. The rectangular prism volume can contain vias that have been filled with one or more different materials. A material in a via can be a conducting metal such as copper. Exemplary solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example the substrate core can be 10 mm by 10 mm up to 250 mm by 250 mm in two dimensions, but substrate cores do not necessarily have to have the same value in both dimensions.

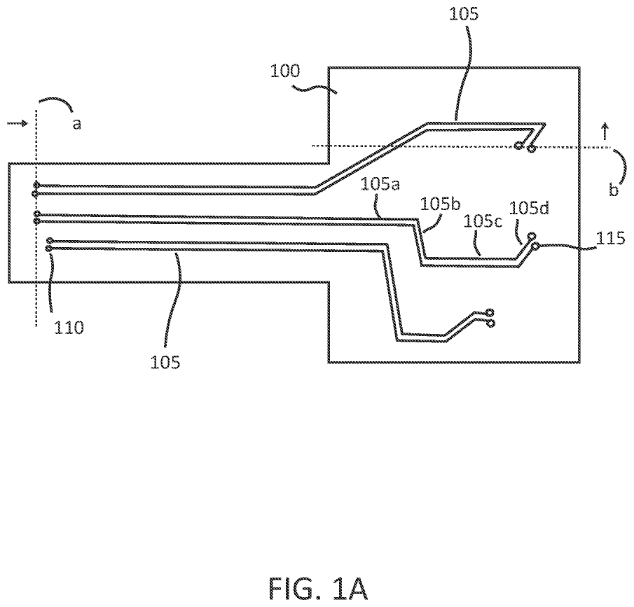

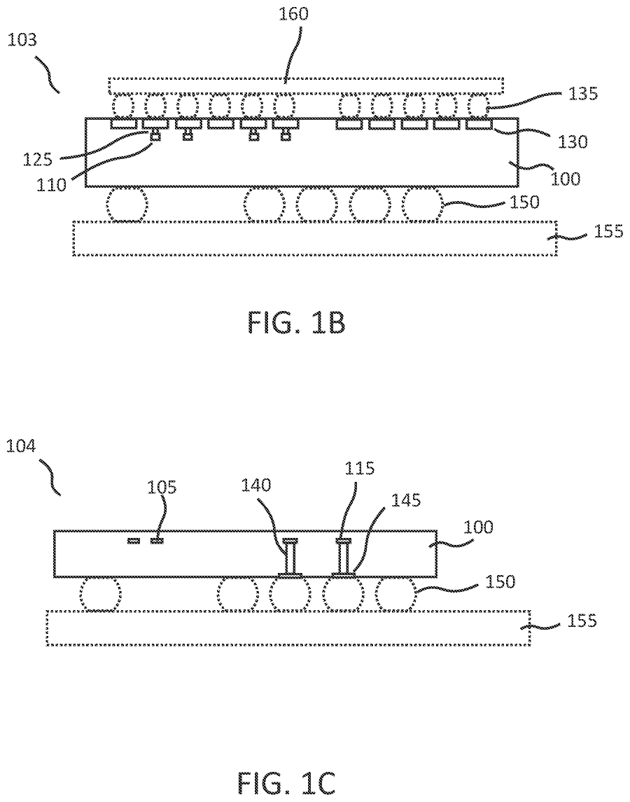

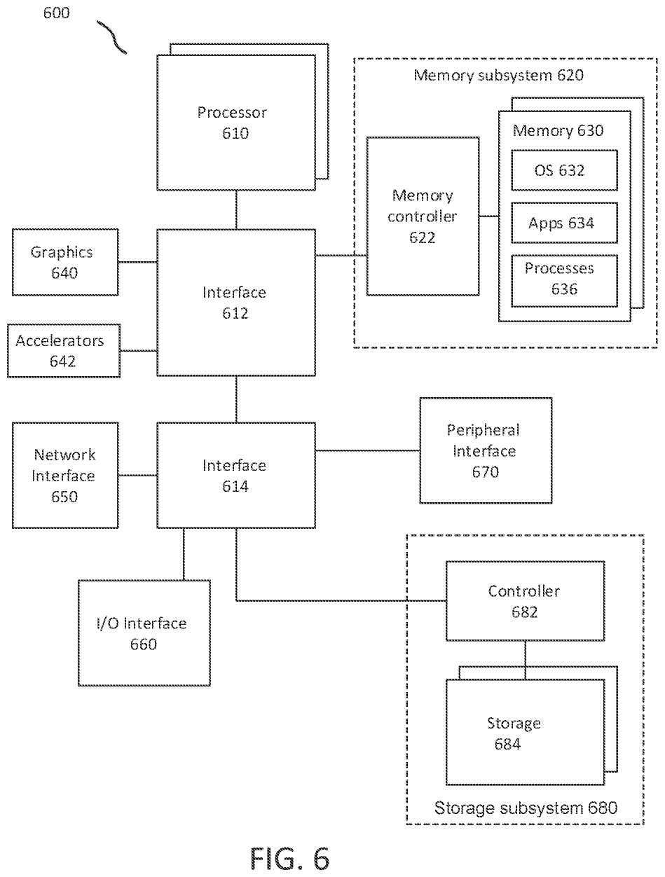

FIGS. 1A-1C provide an illustration of exemplary signal lines 105 in a package substrate 100. Other package substrate shapes, layouts, and numbers of signal lines 105 are possible and a package substrate typically contains other layers and features. For clarity, only part of a complete package is shown and layers, buildup layers, electrical interconnections, power delivery components, ground planes, and devices, for example, have been omitted. In FIG. 1A, a top view of a signal line level is provided. Signal lines 105 are housed in dielectric material which can be one or more layers of dielectric material. FIG. 1B provides a cross section of a package substrate taken along the dashed line labeled “a” and FIG. 1C provides a cross section of a package substrate that is along the dashed line labeled “b” in FIG. 1A. Signal lines 105 are electrically connected to chip-side vias 125 through chip-side connection regions 110. Chip side pads 130 can form an electrical connection to chip connectors 135. Chip connectors 135 can be bumps, pins, rods, solder bumps, or types of electrically conductive features used to join an integrated circuit chip 160 to a packaging substrate 100 and provide power delivery and communication to the integrated circuit chip 160. The integrated circuit chip 160 can be, for example, a chip that is described with respect to FIG. 6 and herein. Signal lines 105 can also be electrically connected to board-side vias 140 through connection regions 115. Vias 140 are electrically connected to board-side pads 145. Board-side pads 145 can connect to board connectors 150 which can be connected to a board 155. Board connectors 150 can be, for example, solder bumps, pins, rods, or other types of electrically conductive features that can be used to join the package substrate 100 to a board 155. Boards 155 generally provide interconnections between semiconductor chips for communications and power delivery, and other devices, such as, for example, power supplies. Boards 155 can be, for example motherboards, mainboards, main circuit boards, printed circuit boards, circuit boards, system boards, or logic boards. Features shown in FIGS. 1A-1C that are shown as dashed lines are not necessarily part of a package substrate 100 but are provided to illustrate an implementation of a package substrate 100. Other implementations are also possible, such as, for example, those having different footprints, geometries, and/or interconnections.

In some exemplary configurations of a package substrate, the signal lines 105 can have a maximum length that is defined by the IEEE (Institute of Electrical and Electronics Engineers) P802.3dj Chanel Operating Margin (COM) reference package design. For example, the package substrate 100 can be a “class A” package substrate that has a maximum trace routing length of 33 mm or a “class B” package having a maximum trace routing length of 45 mm. In FIG. 1A, the maximum length of a signal line 105 (a trace) would be the length of each of the signal line segments 105a, 105b, 105c, and 105d added together. IEEE defines what may be considered as a maximum package substrate loss for end-to-end systems (bump to bump). There is some loss budget allocation defined by 802.03dj and it is known that devices are getting larger and the loss associated with the package is becoming more predominant on the entire channel. “Class A” packages are optimized for loss and “class B” packages are optimized for radix applications. Further, in “class A” packages the ball grid array pitch is defined as 0.8 mm and in “class B” packages it is 1.0 mm. In the examples of FIGS. 1A-1C, the ball grid array pitch is the center-to-center distance between board-side pads 145.

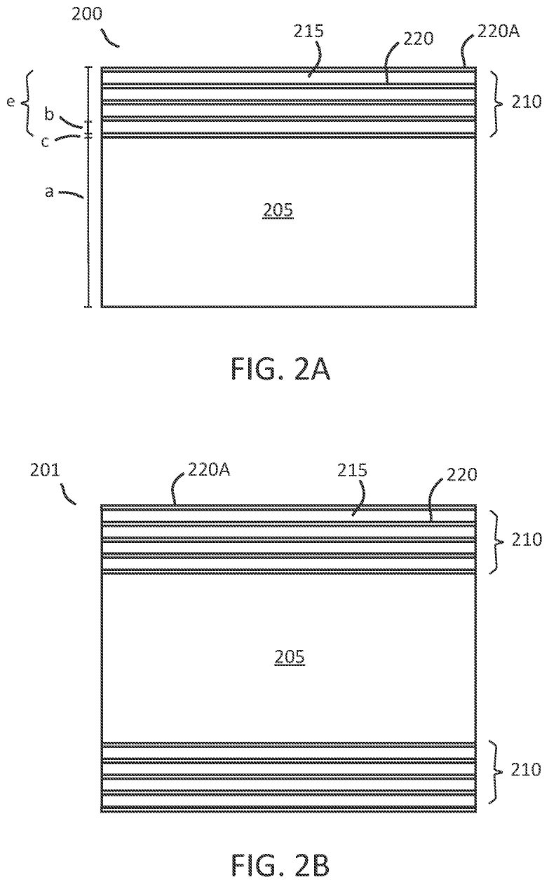

FIGS. 2A-2B illustrate signal lines that are useful, for example, in high speed signaling applications. Signal lines are useful in single-ended and differential signal lines. Applications include interconnect and packaging technologies, such as, for example, the package signal lines illustrated in Figures A-1B. In general, frequency ranges for signaling can be from KHz to Gigahertz. Frequency ranges include, for example, 224 Gbps PAM-4 (pulse amplitude modulation with four levels) signaling from about 50 KHz to 60 GHz. (As used herein, about indicates that value can be +/−10% of the value provided.) Signaling can also be in a high frequency spectrum in a bandwidth of 10 GHz to 30 GHz. High speed signaling is useful, for example, in PCI (peripheral component interconnect), PCIe (PCI express), and ethernet applications, among others.

In FIG. 2A, a signal line 200 includes a first conducting region 205 that has a thickness indicated by “a.” The first conducting region 205 can be a conducting metal, such as, for example, copper, aluminum, gold, platinum, or a conducting material that is non-magnetic. The signal line 200 also includes a meta-conductor region 210 that is comprised of alternating non-magnetic material layers 215 and magnetic material layers 220. In FIG. 2B, the signal line 201 has two meta-conductor regions 210 on opposite sides of the conducting region 205. The non-magnetic material layers 215 can be a conducting metal such as, for example, copper, aluminum, gold, or platinum. The non-magnetic material layers 215 can be a conducting material that is non-magnetic. The magnetic material layers 220 can be a magnetic material such as, for example, cobalt, nickel, iron, or a magnetic material that has a negative permeability. The number of non-magnetic material 215 and magnetic material 220 layer pairs (i.e., one layer of non-magnetic material 215 and one layer of magnetic material 220) can be 1, 2, 3, 4, 5, 6, 7, 8, 9, 10, or more. The thickness “a” of the conducting region 205 can be a value that is, for example, 0.7 μm to 2.5 μm, 1 μm to 2 μm, or 1.2 μm to 2 μm. The magnetic material layer 220 thickness indicated by “c” in FIG. 2A can be, for example a value between, 10 nm and 35 nm, 15 nm and 35 nm, or 15 nm and 30 nm. The non-magnetic material layer 215 thickness indicated by “b” in FIG. 2A, can be, for example a value between, 75 nm and 225 nm, 100 nm and 225 nm, or 125 nm and 200 nm. In additional examples, a ratio between conducting region 205 thickness “a” and magnetic material layer 220 thickness “e” can be between 2 and 20. As shown in FIGS. 2A-2B, there can also be an optional capping magnetic material layer 220A. Signal lines 200 and 201 are housed in a dielectric material, such as, for example, ceramic or organic materials. Organic materials include Ajinomoto build-up film (ABF), polyimides, benzocyclobutene polymers (BCBs), and cyclic-olefin polymers (COP).

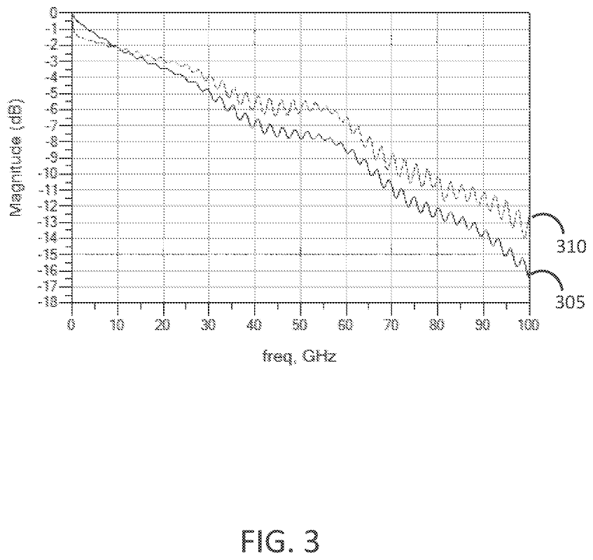

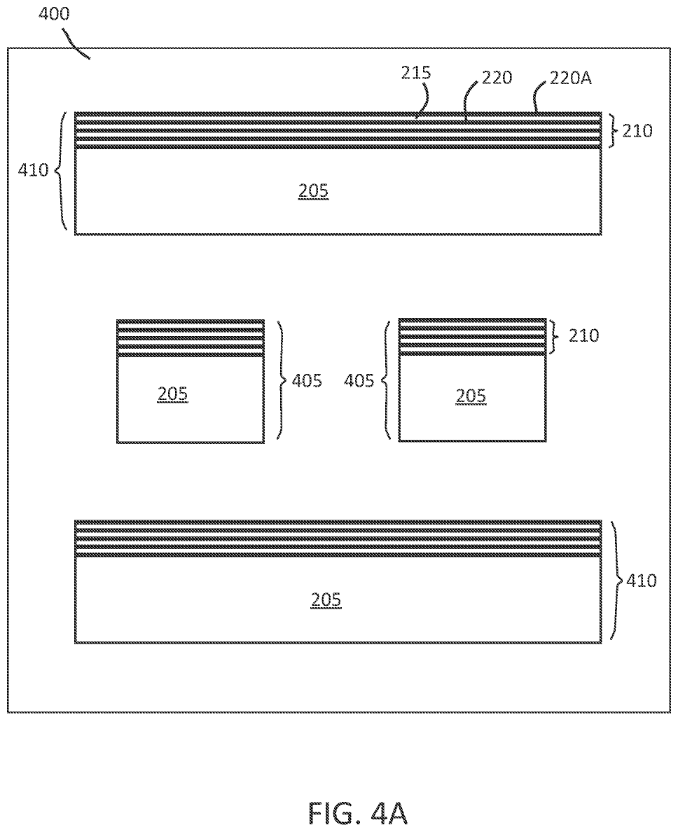

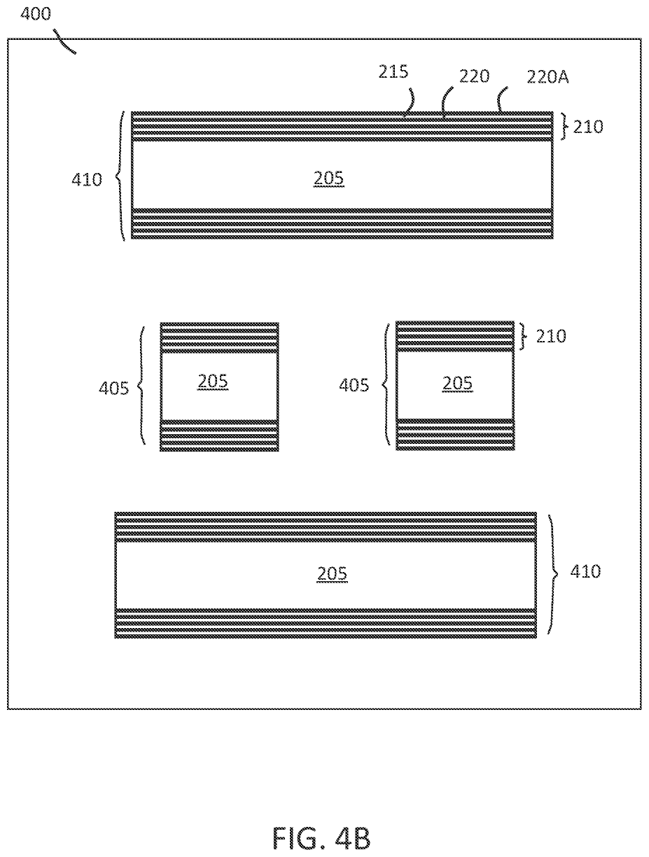

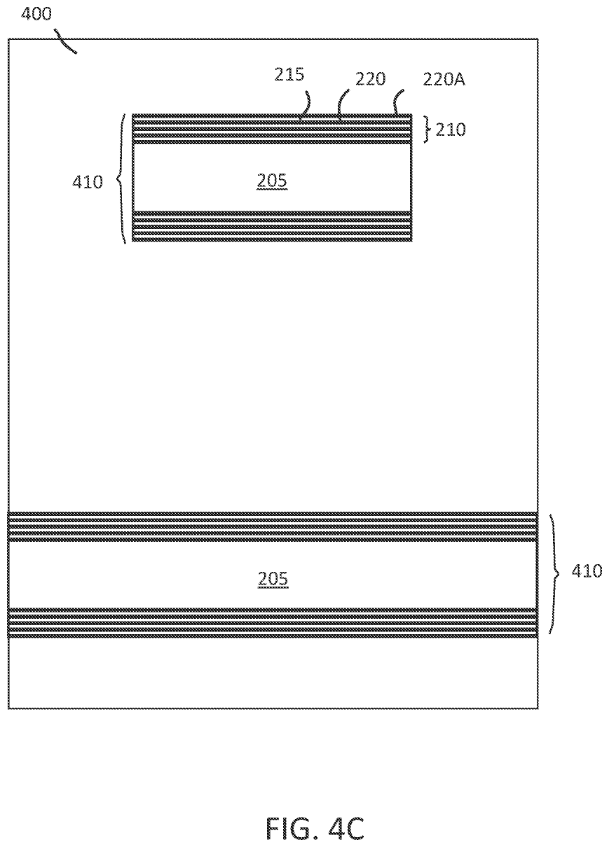

FIG. 3 provides simulation-derived differential insertion loss results for 1) a reference package design defined by IEEE 802.3dj (224 Gbps) using copper signal lines 305 and 2) for an edge-coupled stripline design (e.g., that of FIG. 4) using signal lines similar to those of FIG. 2B (labeled 310). (The signal can also be a microstripline or an edge coupled microstripline.) In the simulation values used for the results 310 were a copper conducting region thickness of 1.75 μm of and in the meta-conductor region, a non-magnetic material thickness of 25 nm of cobalt and a magnetic material thickness of 150 nm of copper. The simulated device had 5 layer pairs in the meta-conductor region and capping layers of magnetic material. Simulation was accomplished using High Frequency Structure Simulation (HFSS, Ansys Inc.) software. FIG. 3 shows the differential loss of a potential reference package defined by IEEE 802.3dj targeting about 8-9 dB loss at Nyquist frequency. As is illustrated in FIG. 3, the simulated device according to FIG. 2B (results 310) delivers less insertion loss (as compared to a copper conductor 305) without any regions of major loss (at low frequency) that can make a device unsuitable for semiconductor package applications. Simulation was done with an edge-coupled stripline topology (one trace is P, another trace is N, side-by-side and GND (ground) above and under). At low frequency, the skin effect can allow energy to flow into the inner regions of the transmission line. Thus, a thick conductive core can enable the transmission line to exhibit normal performance from direct current 0 Hz to 4 GHz. The edge-coupled stripline design was simulated with a 3D-EM tool (electromagnetic simulation software). Launching ports excite the model with Transversal Electromagnetic mode (TEM), using frequency-dependent dielectric characterization and defining the appropriate boundary conditions to preserve passivity, reciprocity, and causality of the resulting scattering-matrix to keep physical consistency.

FIGS. 4A-4C show stripline and microstripline designs that employ signal lines having one or more meta-conductor regions 210, such as those shown in and described with respect to FIGS. 2A-2B. In FIG. 4A, signal lines according to FIG. 2A are illustrated, and in FIGS. 4B-4C signal lines according to FIG. 2B are shown. Additionally, other orientations are possible for the signal lines according to FIG. 2A. For numbering that is the same with respect to FIGS. 4A-4C and FIGS. 2A-2B, the descriptions herein for elements of FIGS. 2A-2B can be used for FIGS. 4A-4C also. A dielectric material 400 houses the ground planes 410 and the conducting strips 405. The dielectric material 400 can be, for example, an organic material such as ABF. The conducting strips 405 and the ground planes 410 include a meta-conductor region 210 that is comprised of alternating non-magnetic material layers 215 and magnetic material layers 220 and an optional end magnetic material layer 220A. Signal lines 200 and 201 of FIGS. 2A-2B can also be used in an edge coupled microstripline or stripline, or a single stripline or microstripline. Although the signal line 201 of FIG. 2B is shown for the microstripline of FIG. 4C, the signal line 200 of FIG. 2A can also be used.

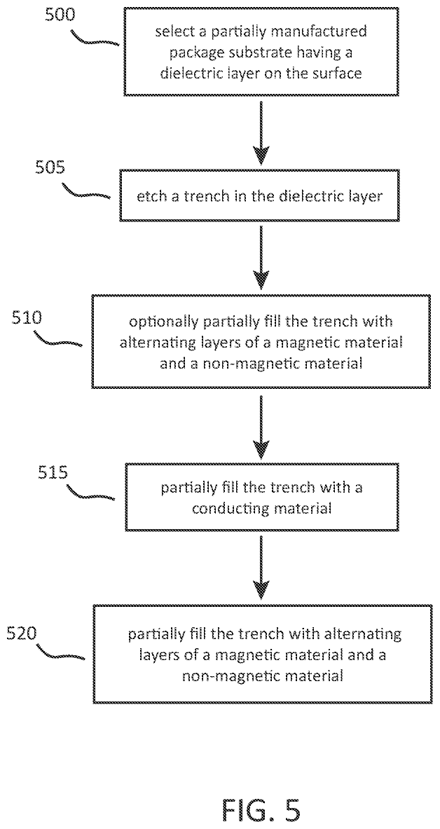

FIG. 5 diagrams a method for manufacturing a package substrate. The method of FIG. 5 can be used to create devices of FIGS. 1A-1C, 2A-2B, and 4, and the descriptions herein for these figures are also applicable here. A partially manufactured package substrate having a layer of dielectric material on a surface is selected 500. A trench is etched in the layer of dielectric material 505. Etching can be done with a plasma etch process or laser drilling process, for example. The trench is optionally partially filled with alternating layers of a magnetic material and a non-magnetic material 510. Layer deposition can be accomplished through one or more deposition processes, such as for example, chemical vapor deposition, atomic layer deposition, or sputtering. If a device according to FIG. 2B is manufactured, for example, the process 510 of partially filling the trench with alternating layers of a magnetic material and a non-magnetic material is performed. The trench is partially filled with a conducting material 515. The conducting material can be deposited through chemical vapor deposition, atomic layer deposition, sputtering. The trench is optionally partially filled with alternating layers of a magnetic material and a non-magnetic material 520 through one or more deposition processes, such as for example, chemical vapor deposition, atomic layer deposition, or sputtering. Useful conducting and/or non-magnetic materials include, for example, copper, aluminum, gold, platinum, or a conducting material that is non-magnetic. The magnetic material layers can be a magnetic material such as, for example, cobalt, nickel, iron, or a magnetic material that has a negative permeability. The number of non-magnetic material and magnetic material layer pairs (i.e., one layer of non-magnetic material 215 and one layer of magnetic material 220) can be 1, 2, 3, 4, 5, 6, 7, 8, 9, 10, or more.

FIG. 6 depicts an example computing system that can include chips that employ packages as described herein, for example with respect to FIGS. 1A-1C, 2A-2B, and 4, and the descriptions herein for these Figures. The computing system employed can include more, different, or fewer features than the one described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or circuit board, printed circuit board, mainboard, system board, or logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 can be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Exemplary systems may be implemented in various types of computing, smart phones, tablets, personal computers, and networking equipment, such as switches, routers, racks, and blade servers such as those employed in a data center and/or server farm environment.

### EXAMPLES

A package substrate can comprise: a dielectric material; and a signal line in the dielectric material wherein the signal line comprises a first region that is comprised of a plurality of layer pairs, wherein the layer pairs comprise a layer of a non-magnetic material and a layer of a magnetic material, wherein there are at least three layer pairs, wherein the signal line comprises a second region that is comprised of a conductive material, wherein the second region has a thickness, the layer of non-magnetic material has a thickness, and the layer of magnetic material has a thickness, and wherein the thickness of the second region is greater than the thickness of the layer of non-magnetic material and the thickness of the layer of magnetic material.

In the package substrate, the layer of magnetic material can be comprised of cobalt, nickel, or iron. The layer of non magnetic material can be comprised of copper. The package substrate can comprise at least five layer pairs. The thickness of the second region can be a value between 0.7 μm and 2.5 μm. The conductive material can be comprised of copper. The first region can have a thickness and a ratio of the thickness of the second region to the first region can be between 2 and 20. The signal line can have a length and the length of the signal line can be 45 mm or less. The package substrate can also include a third region that is comprised of a plurality of layer pairs, wherein the layer pairs include a layer of a non magnetic material and a layer of a magnetic material, wherein there are at least three layer pairs, and wherein the first region and the third region are on opposite sides of the second region.

A semiconductor device can comprise an integrated circuit chip; and a package substrate wherein the package substrate comprises signal lines, wherein the signal lines comprise a first region that is comprised of a plurality of layer pairs, wherein the layer pairs include a layer of a non-magnetic material and a layer of a magnetic material, wherein there are at least four layer pairs, wherein the signal lines comprise a second region that is comprised of a conductive material, wherein the second region has a thickness, the layer of non-magnetic material has a thickness, and the layer of magnetic material has a thickness, and wherein the thickness of the second region is greater than the thickness of the layer of non-magnetic material and the thickness of the layer of magnetic material, and wherein the integrated circuit chip is operably coupled to the package substrate.

In the semiconductor device the layer of magnetic material can be comprised of cobalt, nickel, or iron. The layer of non-magnetic material can be comprised of copper. The thickness of the second region can be a value between 1 μm and 2 μm. The first region has a thickness and a ratio of the thickness of the second region to the first region can be between 2 and 20. The signal lines are electrically connected to chip side pads and the chip side pads are electrically connected to the integrated circuit chip. The signal lines are electrically connected to board side pads and to chip side pads.

A method for manufacturing a semiconductor package can comprise: etching trench in a surface of the semiconductor package substrate wherein the surface comprises a dielectric material; depositing a layer of conducting material wherein the layer of conducting material partially fills the trench wherein the layer of conducting material has a thickness, and wherein the thickness of the layer of conducting material in the trench is between 1 μm and 2 μm; and depositing alternating layers of a magnetic material and a non-magnetic material wherein the alternating layers of magnetic material and non-magnetic material partially fill the trench.

In the method for manufacturing a semiconductor package, the conducting material can be copper, the magnetic material can be cobalt, and the non-magnetic material can be copper. Depositing alternating layers of magnetic material and non-magnetic material can result in 4 layers of magnetic material and 4 layers of non-magnetic material. The magnetic material can be comprised of cobalt, nickel, or iron.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A package substrate comprising:
a dielectric material; and
a signal line in the dielectric material wherein the signal line comprises a first region that is comprised of a plurality of layer pairs, wherein the layer pairs comprise a layer of a non-magnetic material and a layer of a magnetic material, wherein there are at least three layer pairs, wherein the signal line comprises a second region that is comprised of a conductive material, wherein the second region has a thickness, the layer of non-magnetic material has a thickness, and the layer of magnetic material has a thickness, and wherein the thickness of the second region is greater than the thickness of the layer of non-magnetic material and the thickness of the layer of magnetic material.

2. The package substrate of claim 1 wherein the layer of magnetic material is comprised of cobalt, nickel, or iron.

3. The package substrate of claim 1 wherein the layer of non-magnetic material is comprised of copper.

4. The package substrate of claim 1 wherein there are at least five layer pairs.

5. The package substrate of claim 1 wherein the thickness of the second region is a value between 0.7 μm and 2.5 μm.

6. The package substrate of claim 1 wherein the conductive material is comprised of copper.

7. The package substrate of claim 1 wherein the first region has a thickness and a ratio of the thickness of the second region to the first region is between 2 and 20.

8. The package substrate of claim 1 wherein the signal line has a length and the length of the signal line is 45 mm or less.

9. The package substrate of claim 1 also including a third region that is comprised of a plurality of layer pairs, wherein the layer pairs include a layer of a non-magnetic material and a layer of a magnetic material, wherein there are at least three layer pairs, and wherein the first region and the third region are on opposite sides of the second region.

10. A semiconductor device comprising:
an integrated circuit chip; and
a package substrate wherein the package substrate comprises signal lines, wherein the signal lines comprise a first region that is comprised of a plurality of layer pairs, wherein the layer pairs include a layer of a non-magnetic material and a layer of a magnetic material, wherein there are at least four layer pairs, wherein the signal lines comprise a second region that is comprised of a conductive material, wherein the second region has a thickness, the layer of non-magnetic material has a thickness, and the layer of magnetic material has a thickness, and wherein the thickness of the second region is greater than the thickness of the layer of non-magnetic material and the thickness of the layer of magnetic material, and
wherein the integrated circuit chip is operably coupled to the package substrate.

11. The semiconductor device of claim 10 wherein the layer of magnetic material is comprised of cobalt, nickel, or iron.

12. The semiconductor device of claim 10 wherein the layer of non-magnetic material is comprised of copper.

13. The semiconductor device of claim 10 wherein the thickness of the second region is a value between 1 μm and 2 μm.

14. The semiconductor device of claim 10 wherein the first region has a thickness and a ratio of the thickness of the second region to the first region is between 2 and 20.

15. The semiconductor device of claim 10 wherein the signal lines are electrically connected to chip side pads and the chip side pads are electrically connected to the integrated circuit chip.

16. The semiconductor device of claim 10 wherein the signal lines are electrically connected to board side pads and to chip side pads.

17. A method for manufacturing a semiconductor package substrate comprising:
etching trench in a surface of the semiconductor package substrate wherein the surface comprises a dielectric material;
depositing a layer of conducting material wherein the layer of conducting material partially fills the trench wherein the layer of conducting material has a thickness, and wherein the thickness of the layer of conducting material in the trench is between 1 μm and 2 μm; and
depositing alternating layers of a magnetic material and a non-magnetic material wherein the alternating layers of magnetic material and non-magnetic material partially fill the trench.

18. The method of claim 17 wherein the conducting material is copper, the magnetic material is cobalt, and the non-magnetic material is copper.

19. The method of claim 17 wherein depositing alternating layers of magnetic material and non-magnetic material results in 4 layers of magnetic material and 4 layers of non-magnetic material.

20. The method of claim 17 wherein the magnetic material is comprised of cobalt, nickel, or iron.
